(19) United States
(12) Patent Application Publication
(10) Pub. No.: US 2004/0142503 A1
(43) Pub. Date: Jul. 22, 2004

(54) Method of manufacturing highly efficient semiconductor device

(75) Inventors: Jeong-Wook Lee, Kyungki-do (KR); Ji-Beom Yoo, Kyungki-do (KR); Cheol-Soo Sone, Kyungki-do (KR); Youn-Joon Sung, Kyungki-do (KR)

Correspondence Address: BURNS DOANE SWECKER & MATHIS L L P, POST OFFICE BOX 1404, ALEXANDRIA, VA, 22313-1404, US

(73) Assignee: SAMSUNG ELECTRONICS CO., LTD., Kyungki-do (KR)

(21) Appl. No.: 10/660,561

(22) Filed: Sep. 12, 2003

(30) Foreign Application Priority Data
Jan. 21, 2003 (KR) 2003-4106

(51) Int. Cl. H01L 21/00

(52) U.S. Cl. 438/47

(57) ABSTRACT

Provided is a method of manufacturing a semiconductor device. The method includes (a) sequentially stacking a first semiconductor layer, a mask layer, and a metal layer on a substrate; (b) anodizing the metal layer to change the metal layer into a metal oxide layer including a plurality of nanoholes; (c) etching the mask layer using the metal oxide layer as an etch mask until the nanoholes are extended to the surface of the first semiconductor layer; (d) removing the metal oxide layer; and (e) depositing a second semiconductor layer on the mask layer and the first semiconductor layer. The present invention reduces defect density and promotes a uniform defect distribution.

This application claims the priority of Korean Patent Application No. 2003-04106, filed on Jan. 21, 2003, in, the Korean Intellectual Property Office, the contents of which are incorporated herein in their entirety by reference.

### BACKGROUND OF THE INVENTION

1. Field of the Invention

The present invention relates to a method of manufacturing a semiconductor device, and more particularly, to a method of manufacturing a highly efficient semiconductor device, which minimizes defect generation.

2. Description of the Related Art

In a case where an ultraviolet-light emitting diode (UV-LED) is manufactured using a conventional white LED, as is known, the high defect density of a substrate deteriorates optical efficiency of the LED. Typically, when a GaN-related compound semiconductor is grown on a sapphire substrate, threading dislocation occurs due to lattice mismatch and penetrates to reach the surface of the semiconductor without annihilation. During the propagation of the threading dislocation, it also extends into an InGaN active layer and functions as a non-radiative recombination center, thus lowering emitting-efficiency. It is reported that a blue LED or a green LED including an InGaN active layer with a high concentration of In is insensitive to the threading dislocation, while a UV-LED having a low concentration of In is known to be sensitive thereto.

Conventionally, to minimize defects initially grown in a GaN layer by suppressing lattice mismatch, a buffer layer is formed using AlN, AlGaN, InGaN, ZnO, or SiC, or a multi-layered structure for controlling stress is grown. Alternatively, a region unaffected by defects is selectively formed using lateral growth, such as epitaxial lateral overgrowth (ELOG), PENDEO, and LEPS.

FIGS. 1 and 2 are a perspective view and a cross-sectional view of a conventional LED grown using ELOG, respectively.

Referring to FIGS. 1 and 2, a first GaN layer 13 is stacked on a substrate 11, and then a mask layer 15 is formed as a stripe pattern thereon. The mask layer 15 shields a portion of the first GaN layer 13 and prevents vertical growth of a defect D, which occurs due to lattice mismatch generated between the sapphire substrate 11 and the first GaN layer 13. Next, a second GaN layer 17 is re-grown on the first GaN layer 13 and the mask layer 15.

A portion of the defect D is not shielded by the mask layer 13 and is grown in a vertical direction as shown in FIGS. 1 and 2. The defect D, which is grown closely to the mask layer 13, wraps around the mask layer 15 and is grown in a lateral direction. The defect D is grown from both sides of the mask layer 15 toward the center of the mask layer 15 in a lateral direction and then grown again in a vertical direction from around the center of the mask layer 15. Due to such growth pattern, the defect D is suppressed in a region ranging from the center of the mask layer 15 to both sides thereof, thus locally increasing emitting-efficiency.

Nevertheless, according to conventional ELOG epitaxial growth, the defect D still remains at an opening formed in the mask layer 13. Therefore, a difference in emitting-efficiency occurs between a low-defect region of the mask layer 13 and other high-defect regions, thus degrading the whole emitting distribution. Also, semiconductor devices other than LEDs should also be manufactured using techniques that minimize lattice mismatch.

### SUMMARY OF THE INVENTION

The present invention provides a method of manufacturing a semiconductor device which has a reduced lattice density and a uniform defect distribution.

In accordance with an aspect of the present invention, there is provided a method of manufacturing a semiconductor device, which comprises (a) sequentially stacking a first semiconductor layer, a mask layer, and a metal layer on a substrate; (b) anodizing the metal layer to transform the metal layer into a metal oxide layer including a plurality of nanoholes; (c) etching the mask layer using the metal oxide layer as an etch mask until the nanoholes are extended to the surface of the first semiconductor layer; (d) removing the metal oxide layer by etching; and (e) depositing a second semiconductor layer on the mask layer and the first semiconductor layer.

Preferably, each of the holes has a diameter of about 10 nm to 500 nm and occupies less than 50% of the entire area.

The mask layer is preferably formed to a thickness of about 50 nm to 500 nm.

The first semiconductor layer has a lattice constant which is different from that of the substrate.

The substrate is formed of one of an inorganic crystal including sapphire, Si, SiC, MaAl₂O₄, NdGaO₃, LiGaO₂, ZnO, or MAG, a III-V group compound semiconductor including GaP or GaAs, and a III group nitride semiconductor including GaN.

The first and second semiconductor layers are formed of a nitride semiconductor, which is GaN, InGaN, AlGaN, AlInGan, or InGaNAs.

The mask layer is formed of a polycrystalline semiconductor, a dielectric material, or a metal. Preferably, the polycrystalline semiconductor layer is polysilicon or polycrystalline nitride, and the dielectric material is silicon oxide, titanium oxide, or zirconium oxide. Also, the metal is titanium or tunsten, which has a melting point of 1200° C. or higher.

In step (c), the etching process is a dry etch process, and an electrical charge storing material may be further deposited in the nanoholes.

In step (e), electrical charge storing material is further deposited in the nanoholes.

In the present invention, a nanopatterned mask layer is formed using an anodic aluminum oxide technique. Thus, the defect density decreases and a uniform defect distribution can be obtained.

### BRIEF DESCRIPTION OF THE DRAWINGS

The above and other features and advantages of the present invention will become more apparent by describing in detail preferred embodiments thereof with reference to the attached drawings in which:

FIG. 1 is a schematic perspective view of a conventional LED;

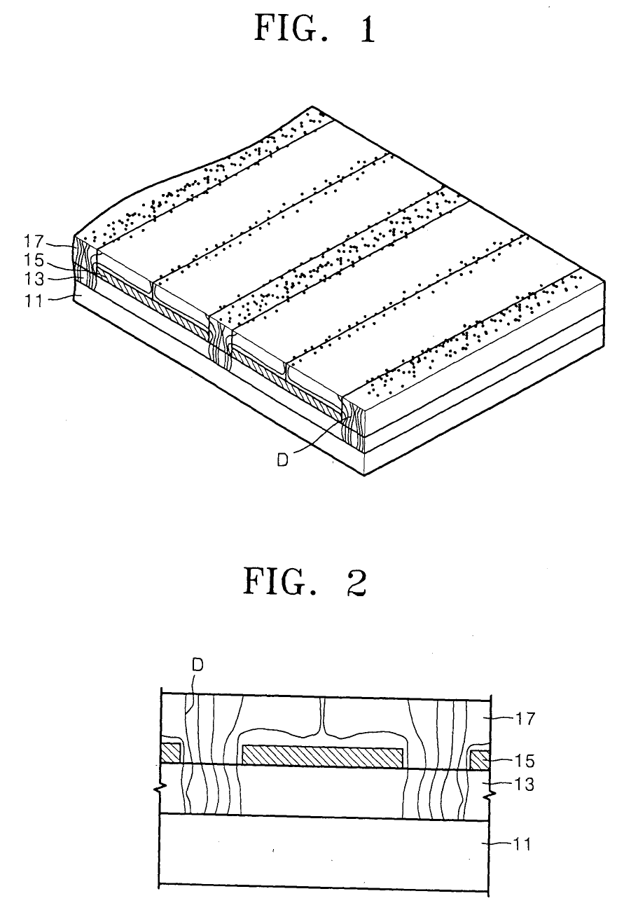

FIG. 2 is a schematic cross-sectional view of the conventional LED of FIG. 1;

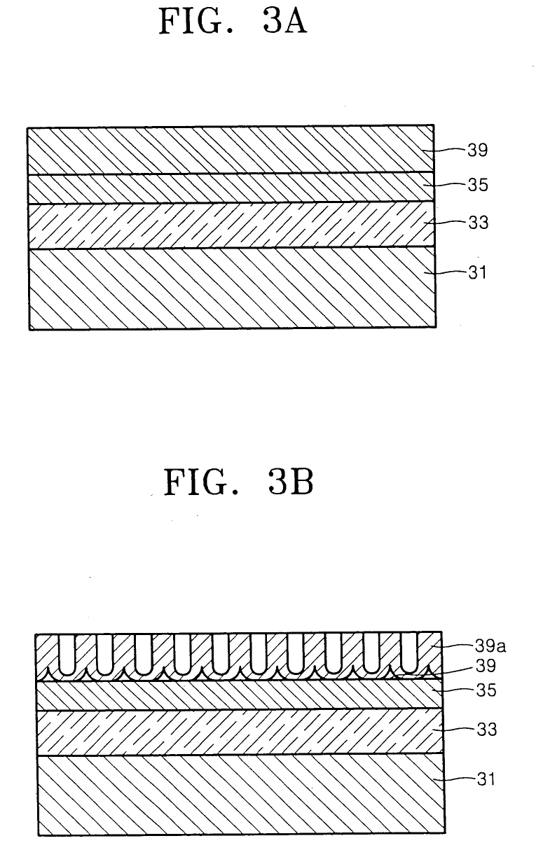

FIGS. 3A through 3E are cross-sectional views illustrating a method of manufacturing a semiconductor device according to an embodiment of the present invention;

FIG. 4 is a perspective view of an LED formed according to an embodiment of the present invention; and

FIG. 5 is a cross-sectional view of an LED formed according to another embodiment of the present invention.

### DETAILED DESCRIPTION OF THE INVENTION

The present invention will now be described more fully with reference to the accompanying drawings, in which preferred embodiments of the invention are shown.

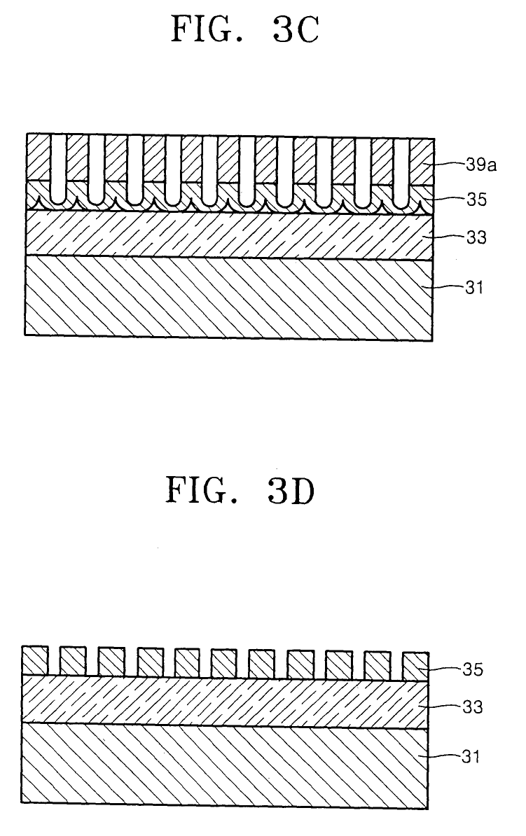

FIGS. 3A through 3E are cross-sectional views illustrating a method of manufacturing a semiconductor device, which allows suppression of defect generation, according to an embodiment of the present invention.

As shown in FIG. 3A, a first semiconductor layer 33, a mask layer 35, and a metal layer 39 are sequentially stacked on a substrate 31. The substrate 31 is formed of one selected from the group consisting of an inorganic crystal including sapphire, Si, SiC, MaAl₂O₄, NdGaO₃, LiGaO₂, ZnO, or MaO, a III-V group compound semiconductor including GaP or GaAs, and a III group nitride semiconductor including GaN. A sacrificial layer formed of, for example, Ti, may be interposed between the mask layer 35 and the metal layer 39 to aid adhesion of the mask layer 35 and the metal layer 39.

As shown in FIG. 3B, the metal layer 39 is anodized to form a metal oxide layer 39a where a plurality of nanoholes are arranged. The metal layer 39 is generally formed of aluminum, which is changed into alumina by anodization, allowing formation of a plurality of nanoholes on its surface. Here, each of the holes is preferably formed to a diameter of 100 nm or less.

FIG. 3C shows a dry etch process. That is, the mask layer 35 is dry etched using the metal oxide layer 39a as an etch mask. Thus, the holes arranged in the metal oxide layer 39a can be extended to the surface of the first semiconductor layer 33.

After the dry etch process is performed, the metal oxide layer is removed using etching. As a result, as shown in FIG. 3D, only the mask layer 35 having the nanopattern remains on the first semiconductor layer 33. The mask layer 35 may be formed of a polycrystalline semiconductor, a dielectric material, or a metal. Preferably, the polycrystalline semiconductor layer is polysilicon or polycrystalline nitride, and the dielectric material is silicon oxide, titanium oxide, or zirconium oxide. Also, the metal is titanium or tungsten, which has a melting point of 1200° C. or higher.

A second semiconductor layer 38 is deposited on the mask layer 35 and the first semiconductor layer 33. Thus, as shown in FIG. 3E, a semiconductor device is completed. In a case where the second semiconductor layer 38 is re-grown by using the mask layer 35 having the nanopattern as a mask, propagation of defects can be prevented using selective growth. Also, if the second semiconductor layer 38 is subsequently re-grown on the nanopattern, abnormal defect distribution can be minimized at an interface between the second semiconductor layer 38 and the nanopattern, thus maintaining a stable structure of the semiconductor device. While the first and second semiconductor layers 33 and 43 may be formed of a nitride semiconductor, such as GaN, it is possible to use various materials according to the type of the semiconductor device. Alternatively, a plurality of other semiconductor layers may be deposited on the second semiconductor layer 38.

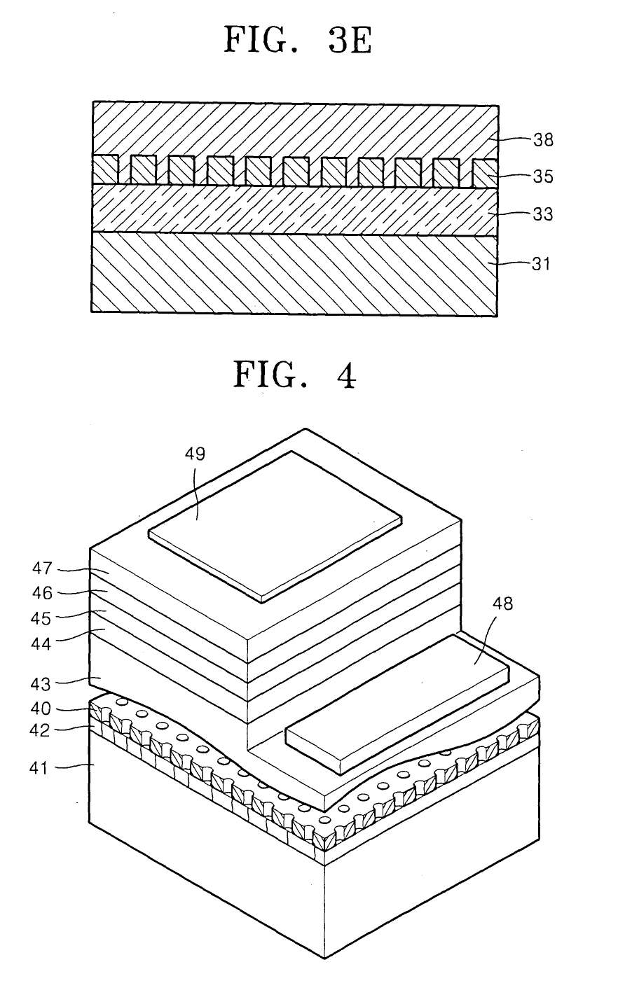

FIG. 4 is a perspective view of an LED formed according to an embodiment of the present invention, as shown in FIGS. 3A through 3E.

Referring to FIG. 4, a GaN buffer layer 42 is stacked on a sapphire substrate 41, and a SiO₂ layer 40, where nanoholes are arranged in stripes or hexagons, is patterned on the GaN buffer layer 42. An n-GaN layer 43 is deposited on the SiO₂ layer 40. The SiO₂ layer 40 for a mask layer prevents propagation of threading dislocation, which occurs at an interface between the substrate 41 and the GaN buffer layer 42. Thus, the defect density decreases, and the nanoholes are uniformly distributed, enabling uniform defect distribution. An n-AlGaN layer 44 for a lower clad layer, an InGaN layer 45 for an active layer, and a p-AlGaN layer 46 for an upper clad layer are sequentially stacked on the n-GaN layer 43. An n-type electrode 48 is formed on a step of the n-GaN layer 43, and a p-type electrode 49 is formed on the p-AlGaN layer 46.

Since the SiO₂ layer 40, which is interposed between the GaN buffer layer 42 and the n-GaN layer 43, prevents propagation of defects, emitting-efficiency of the active layer 45 increases. In the present embodiment, the the SiO₂ layer 40 is formed as a mask layer between the GaN buffer layer 42 and the n-GaN layer 43. However, a mask layer may be positioned at an interface between the n-GaN layer 43 and the n-AlGaN layer 44, or between any semiconductor layers. In a case where a plurality of mask layers are patterned at interfaces between every two semiconductor layers, resulting upper and lower patterns may be formed to intersect each other. As a result, defect density can markedly decrease and a uniform defect distribution can be obtained. For example, dislocation, which is propagated by penetrating a portion of the first mask layer including the holes, is not propagated anymore and is cut off by the second mask layer patterned at an intersection of the first mask layer and the holes. By making nanopatterns of the mask layers intersect each other, the defect density can be greatly decreased, thus enabling formation of highly efficient emitting devices.

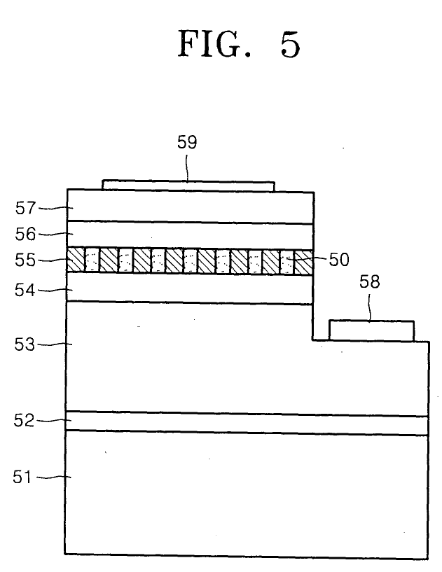

FIG. 5 is a cross-sectional view of an LED according to another embodiment of the present invention, where nanoholes are used as quantum points.

As shown in FIG. 5, an emitting device having quantum points can be manufactured by pattering a mask layer 55 on a lower clad layer 54 and then filling nanoholes of the mask layer 55 with electric charge storing material 50. Here, reference numeral 51 denotes a substrate, 52 denotes a buffer layer, 53 denotes a first compound semiconductor layer, 56 denotes an upper clad layer, 57 denotes a second compound semiconductor layer, 58 denotes an n-type electrode, and 59 denotes a p-type electrode.

In a case where an active layer is formed of a mask layer having quantum points according to the present invention, since the number of electrons trapped in the quantum points is small, an emitting device can emit light even at a low driving voltage. Also, defect growth can be suppressed, thus improving emitting-efficiency.

While the present invention has been particularly shown and described with reference to preferred embodiments thereof, it will be understood by those of ordinary skill in the art that various changes in form and details may be made therein without departing from the spirit and scope of the present invention as defined by the following claims. For example, those of ordinary skill in the art can manufacture a mask layer having various-shaped nanopatterns.

What is claimed is:

1. A method of manufacturing a semiconductor device, the method comprising:
(a) sequentially stacking a first semiconductor layer, a mask layer, and a metal layer on a substrate;
(b) anodizing the metal layer to transform the metal layer into a metal oxide layer including a plurality of nanoholes;
(c) etching the mask layer using the metal oxide layer as an etch mask until the nanoholes are extended to the surface of the first semiconductor layer;
(d) removing the metal oxide layer by etching; and
(e) depositing a second semiconductor layer on the mask layer and the first semiconductor layer.

2. The method of claim 1, wherein each of the holes has a diameter of about 10 nm to 500 nm.

3. The method of claim 1, wherein each of the holes occupies less than 50% of the entire area.

4. The method of claim 1, wherein the mask layer is formed to a thickness of about 50 nm to 500 nm.

5. The method of claim 1, wherein the first semiconductor layer has a lattice constant which is different from the lattice constant of the substrate.

6. The method of claim 1, wherein the substrate is formed of one of an inorganic crystal including sapphire, Si, SiC, MaAl₂O₄, NdGaO₃, LiGaO₂, ZnO, or MaO, a III-V group compound semiconductor including GaP or GaAs, and a III group nitride semiconductor including GaN.

7. The method of claim 1, wherein the first semiconductor layer and the second semiconductor layer are formed of nitride semiconductors.

8. The method of claim 7, wherein the nitride semiconductor is one of GaN, InGaN, AlGaN, AlInGan, and InGaNAs.

9. The method of claim 1, wherein the mask layer is formed of one of a polycrystalline semiconductor, a dielectric material, and a metal.

10. The method of claim 9, wherein the polycrystalline semiconductor layer is one of polysilicon and polycrystalline nitride.

11. The method of claim 9, wherein the dielectric material is one of silicon oxide, titanium oxide, and zirconium oxide.

12. The method of claim 9, wherein the metal has a melting point of 1200° C. or higher.

13. The method of claim 12, wherein the metal is one of titanium and tungsten.

14. The method of claim 1, wherein the metal layer is formed of aluminum.

15. The method of claim 1, wherein in step (c), the etching process is a dry etch process.

16. The method of claim 1, wherein in step (e), electrical charge storing material is further deposited in the nanoholes.
